(19) United States
(12) Patent Application Publication
(10) Pub. No.: US 2018/0254386 A1
(43) Pub. Date: Sep. 6, 2018

(54) OPTOELECTRONIC SEMICONDUCTOR COMPONENT AND METHOD OF PRODUCING SAME

(71) Applicant: OSRAM Opto Semiconductors GmbH, Regensburg (DE)

(72) Inventors: Korbinian Perzlmaier, Regensburg (DE); Anna Kasprzak-Zablocka, Donaustauf (DE); Lutz Höppel, Alteglofsheim (DE); Christian Leirer, Friedberg (DE)

(21) Appl. No.: 15/756,676

(22) PCT Filed: Aug. 22, 2016
(86) PCT No.: PCT/EP2016/069813

§ 371 Date: Mar. 1, 2018

(30) Foreign Application Priority Data
Sep. 1, 2015 (DE) 10 2015 114 587.1

(51) Int. Cl. H01L 33/48; H01L 33/62; H01L 33/58; H01L 33/60

(52) U.S. Cl. CPC H01L 33/486; H01L 33/60; H01L 33/58; H01L 33/62

(57) ABSTRACT

An optoelectronic semiconductor component includes an active layer arranged between a p-type semiconductor region and an n-type semiconductor region, a carrier including a plastic and a first via and a second via, a p-contact layer and an n-contact layer arranged between the carrier and a semiconductor body at least in some regions, wherein the p-contact layer electrically joins the first via and the p-type semiconductor region, and the n-contact layer electrically joins the second via and the n-type semiconductor region, a metallic reinforcing layer arranged at least in some regions between the n-contact layer and the carrier, wherein the metallic reinforcing layer is at least 5 μm thick, and at least one p-contact feed-through arranged between the first via and the p-contact layer, wherein the p-contact feed-through is at least 5 μm thick and surrounded in a lateral direction by the reinforcing layer at least in some regions.

### TECHNICAL FIELD

This disclosure relates to an optoelectronic semiconductor component comprising a semiconductor body and a carrier composed of a plastics material, and to a method of producing same.

### BACKGROUND

Optoelectronic semiconductor components can comprise in particular a semiconductor body and a plastic carrier produced by a molding method, which is provided with vias for the electrical contacting of the semiconductor body.

There is nonetheless a need to provide an improved optoelectronic semiconductor component distinguished by improved mechanical and/or electro-optical properties and that can be produced comparatively easily.

### SUMMARY

We provide an optoelectronic semiconductor component including a semiconductor body including a semiconductor layer sequence having a p-type semiconductor region, an n-type semiconductor region and an active layer arranged between the p-type semiconductor region and the n-type semiconductor region, a carrier including a plastic and a first via and a second via, a p-contact layer and an n-contact layer arranged between the carrier and the semiconductor body at least in some regions, wherein the p-contact layer electrically joins the first via and the p-type semiconductor region, and the n-contact layer electrically joins the second via and the n-type semiconductor region, a metallic reinforcing layer arranged at least in some regions between the n-contact layer and the carrier, wherein the metallic reinforcing layer is at least 5 μm thick, and at least one p-contact feed-through arranged between the first via and the p-contact layer, wherein the p-contact feed-through is at least 5 μm thick and surrounded in a lateral direction by the reinforcing layer at least in some regions.

We also provide a method of producing an optoelectronic semiconductor component including a semiconductor body including a semiconductor layer sequence having a p-type semiconductor region, an n-type semiconductor region and an active layer arranged between the p-type semiconductor region and the n-type semiconductor region, a carrier including a plastic and a first via and a second via, a p-contact layer and an n-contact layer arranged between the carrier and the semiconductor body at least in some regions, wherein the p-contact layer electrically joins the first via and the p-type semiconductor region, and the n-contact layer electrically joins the second via and the n-type semiconductor region, a metallic reinforcing layer arranged at least in some regions between the n-contact layer and the carrier, wherein the metallic reinforcing layer is at least 5 μm thick, and at least one p-contact feed-through arranged between the first via and the p-contact layer, wherein the p-contact feed-through is at least 5 μm thick and surrounded in a lateral direction by the reinforcing layer at least in some regions, including producing the reinforcing layer and the p-contact feed-through by electroplating.

### BRIEF DESCRIPTION OF THE DRAWINGS

FIG. 1 shows a schematic illustration of a cross section through an optoelectronic component according to a first example.

FIGS. 2A to 2M show a schematic illustration of an example of the method of producing the optoelectronic component with the aid of intermediate steps.

FIG. 3 shows a schematic illustration of a cross section through an optoelectronic component according to a second example.

FIG. 4 shows a schematic illustration of a cross section through an optoelectronic component according to a third example.

### LIST OF REFERENCE NUMBERS

1 semiconductor body

2 semiconductor layer sequence

3 p-type semiconductor region

4 active layer

5 n-type semiconductor region

6 p-contact layer

7 p-contact feed-through

8 n-contact layer

8A n-through-contact

9 encapsulating layer

10 carrier

11 first via

12 second via

13 electrically insulating layer

14 reinforcing layer

15 electrically insulating layer

16 radiation exit surface

17 first main surface

18 second main surface

19 electrically insulating layer

20 converter layer

21 side wall of the semiconductor layer sequence

22 side wall of the semiconductor component

23 growth substrate

24 opening

25 opening

26 opening

27 light-absorbing or reflective layer

28 chamfer

29 rear contact

30 rear contact

100 optoelectronic semiconductor component

### DETAILED DESCRIPTION

Our optoelectronic semiconductor component may comprise a semiconductor body, which comprises a semiconductor layer sequence having a p-type semiconductor region, an n-type semiconductor region and an active layer arranged between the p-type semiconductor region and the n-type semiconductor region. The active layer can be in particular a radiation-emitting active layer. The p-type semiconductor region, the n-type semiconductor region and the active layer can each comprise one or more semiconductor layers. The p-type semiconductor region contains one or more p-doped semiconductor layers and the n-doped semiconductor region contains one or more n-doped semiconductor layers. It is also possible that the p-type semiconductor region and/or the n-type semiconductor region contain(s) one or more undoped semiconductor layers.

The active layer can be in the form of, for example, a p-n junction, a double heterostructure, a single quantum well structure or a multiple quantum well structure. The term “quantum well structure” comprises any structure in which charge carriers undergo quantization of their energy states by confinement. In particular, the term “quantum well structure” carries no implication as to the dimensionality of the quantization. It therefore includes, among other things, quantum wells, quantum wires and quantum dots and any combination of such structures.

Furthermore, the optoelectronic semiconductor component comprises a carrier comprising a plastic. The carrier can be produced in particular by a molding method. In other words, the carrier is a so-called “molded body”. The term “molding method” includes all production methods in which a molding composition is brought into a predefined shape and in particular is subsequently cured. In particular, the term “molding method” comprises casting or potting, injection molding, transfer molding and compression molding. The carrier is preferably formed by compression molding or a film-assisted molding method (film-assisted transfer molding).

The plastic of the carrier preferably comprises a casting resin such as e.g. an epoxy resin or a silicone. The plastic can contain one or more additives as an admixture. For example, the carrier can comprise SiO₂ particles to adjust the coefficient of thermal expansion. The carrier can, for example, have a thickness of 80 μm to 500 μm, preferably 100 μm to 200 μm and typically about 100 μm.

The carrier may have a first via and a second via, each routed from a first main surface of the carrier facing towards the semiconductor body to a second main surface of the carrier facing away from the semiconductor body.

Owing to the fact that the vias are routed from the first main surface of the carrier to the opposite second main surface of the carrier, the optoelectronic component can advantageously be provided with electrical connections on the second main surface of the carrier. In particular, the optoelectronic component can be joined on the second main surface of the carrier to traces on a printed circuit board, e.g. by joining the first via to a first trace on a printed circuit board using a solder layer and the second via to a second trace on the printed circuit board using a second solder layer. The optoelectronic component is therefore advantageously surface-mountable.

Furthermore, the optoelectronic semiconductor component advantageously comprises a p-contact layer and an n-contact layer arranged at least in some regions between the carrier and the semiconductor body, the p-contact layer being electrically joined to the first via and the p-type semiconductor region, and the n-contact layer being electrically joined to the second via and the n-type semiconductor region. The p-contact layer and the n-contact layer are insulated from one another by at least one electrically insulating layer. Advantageously, both the p-type semiconductor region and the n-type semiconductor region are contacted from the carrier side in the optoelectronic semiconductor chip. This has the advantage that a radiation exit surface of the semiconductor body opposite the carrier can be free from connection layers. The radiation yield is advantageously increased in this way.

Furthermore, it is advantageous if the n-contact layer and/or the p-contact layer is/are reflective for the radiation emitted by the active layer to reflect radiation emitted in the direction of the carrier towards the radiation exit surface. The n-contact layer and/or the p-contact layer can comprise in particular a reflective metal layer and preferably contain(s) silver, gold, or aluminum. It is possible that the n-contact layer and/or the p-contact layer comprise(s) multiple sub-layers, in particular a metal layer and a layer composed of a transparent conductive oxide such as e.g. ITO or doped ZnO, wherein the dopant can be, for example, Al or Ga.

The optoelectronic semiconductor component advantageously comprises a metallic reinforcing layer arranged at least in some regions between the semiconductor layer sequence and the carrier. The metallic reinforcing layer is in particular arranged at least in some regions between the n-contact layer and the carrier. The metallic reinforcing layer contains a metal or a metal alloy and is at least 5 μm, particularly preferably at least 10 μm, thick. As a result of the comparatively thick metallic reinforcing layer between the carrier and the semiconductor layer sequence, improved mechanical stability is achieved in the optoelectronic semiconductor component. The metallic reinforcing layer can, at least in some regions, directly adjoin the carrier and/or can be separated from the carrier by a dielectric layer.

Furthermore, the optoelectronic semiconductor component comprises a p-contact feed-through arranged between the first via and the p-contact layer. The p-contact feed-through, like the metallic reinforcing layer, advantageously comprises a metal or a metal alloy.

The at least one p-contact feed-through, like the metallic reinforcing layer, may be at least 5 μm, preferably at least 10 μm, thick. In particular, the p-contact feed-through can be produced by electroplating. The at least one p-contact feed-through is preferably surrounded by the reinforcing layer in a lateral direction, at least in some regions. In other words, the p-contact feed-through and the reinforcing layer lie in one plane, at least in some regions. The p-contact feed-through does not directly adjoin the reinforcing layer here, but is advantageously insulated from the reinforcing layer by an electrically insulating layer, the electrically insulating layer being preferably no more than 5 μm thick. Preferably, with the exception of the region of the electrically insulating layer, the entire area of the optoelectronic semiconductor component arranged between the carrier and the semiconductor layer sequence is covered either by the metallic reinforcing layer or by the p-contact feed-through. The two comparatively thick layers of the metallic reinforcing layer and the p-contact feed-through thus together form a mechanical reinforcement of the optoelectronic semiconductor component on the surface facing towards the carrier.

At an interface facing towards the carrier, the metallic reinforcing layer preferably has an RMS roughness of at least 50 nm. Owing to the fact that, at an interface facing towards the carrier, the metallic reinforcing layer has an RMS roughness of at least 50 nm, preferably of at least 100 nm, particularly preferably of at least 200 nm, adhesion of the carrier and/or of the dielectric layer to the metallic reinforcing layer is advantageously improved and thus the mechanical stability of the optoelectronic semiconductor component is further improved.

The metallic reinforcing layer preferably contains or consists of nickel or copper. A nickel layer or copper layer can be produced in a simple manner, in particular by electroplating, with comparatively high roughness, the RMS roughness being at least 50 nm or even at least 200 nm. A separate process step of roughening the metallic reinforcing layer, e.g. an etching process, can, but does not necessarily have to, be carried out if an RMS roughness of at least 50 nm is already obtained during electroplating. This can be achieved e.g. by not adding any additives causing a reduction in the surface roughness of the deposited layer to the electrolytic bath for the electroplating of the metallic reinforcing layer. In particular, in the electroplating of a nickel layer or copper layer, a layer with an RMS roughness of more than 50 nm can be obtained in the electrolytic bath, which layer does not need to be roughened by a separate process step.

A dielectric layer may be arranged between the carrier and the metallic reinforcing layer. The dielectric layer is preferably an inorganic layer, particularly preferably a silicon oxide layer. The dielectric layer is preferably formed conformally to the metallic reinforcing layer. In other words, the surface of the dielectric layer preferably has substantially the same roughness as the metallic reinforcing layer. The RMS roughness of the dielectric layer can be in particular at least 50 nm, preferably at least 100 nm, particularly preferably at least 200 nm. The dielectric layer can directly adjoin the carrier and improve adhesion of the carrier owing to its roughness. Because of the roughness of the metallic reinforcing layer, which is transferred into the dielectric layer, adhesion of the dielectric layer to the metallic reinforcing layer is also improved.

The dielectric layer is preferably arranged at least partly between the metallic reinforcing layer and the p-contact feed-through. The dielectric layer is preferably deposited after depositing the metallic reinforcing layer and also covers the side walls of the metallic reinforcing layer. The p-contact feed-through is preferably produced after depositing the dielectric layer in an opening in the metallic reinforcing layer, the side walls of the reinforcing layer facing towards the opening being provided with the dielectric layer.

The semiconductor layer sequence may be surrounded by the carrier in a lateral direction, at least in some regions. In this way, the sides of the semiconductor layer sequence are protected by the carrier. The semiconductor layer sequence preferably does not adjoin the carrier directly at any point, but is separated from the carrier by at least one metallic and/or dielectric layer. The plastics material of the carrier is thus advantageously protected from the radiation emitted by the active layer. In particular, viewed in a lateral direction, the reinforcing layer can be arranged between the semiconductor layer sequence and the carrier at least in some regions. In this way, the metallic reinforcing layer brings about improved mechanical stability and a protection of the semiconductor layer sequence even in a sideways direction.

The optoelectronic semiconductor component may have oblique side walls formed at least in some regions by external sides of the carrier. The side walls preferably run obliquely such that a cross section of the optoelectronic component tapers from the carrier towards a radiation exit surface. In other words, the optoelectronic component is wider on the carrier side than on a radiation exit surface opposite the carrier. This has the advantage that, when gripped from the side, the optoelectronic semiconductor chip is touched substantially only on the side of the carrier while any layers arranged on the radiation exit surface are not touched.

This is an advantage in particular in a preferred example in which a converter layer is arranged on a radiation exit surface of the optoelectronic semiconductor chip. The converter layer can contain one or more luminescence conversion substances, which are embedded e.g. in a matrix material such as, for example, a silicone. The converter layer is advantageously not touched when the chip is gripped from the side owing to the oblique side walls so that in particular there is no risk of the converter layer being damaged and/or the gripping tool being contaminated with material of the converter layer.

Preferably, the converter layer projects over the semiconductor layer sequence in a lateral direction by a length L of at least 5 μm, preferably between at least 5 μm and no more than 50 μm. In this way, an emission at the edge of the optoelectronic semiconductor chip of radiation which has not passed through the converter layer and, for example, gives an undesirable blue color impression is advantageously avoided. It is furthermore also possible that the converter layer projects laterally over the preferably oblique side walls.

Advantageously, the converter layer has a chamfer. In other words, the edge of the converter layer at the surface is formed not at a right angle, but obliquely, e.g. at a 45° angle to the surface of the converter layer, or the edge is rounded. In this way, light emitted in the direction of the upper edge of the converter layer is prevented from travelling a particularly long distance through the converter layer and therefore comprising an excessive proportion of converted light.

Further advantageously, side surfaces of the converter layer are covered with a light-absorbing or reflective layer. In this way, an emission at the edge of the converter layer of light which, compared to light emitted in a perpendicular direction, has travelled a very great distance in the converter layer and therefore gives a different color impression, e.g. a yellowish color impression, is prevented.

In a light-absorbing layer, this preferably has a varying thickness which increases towards a surface of the converter layer. In this way, the light emitted at the upper edge of the converter layer, which has travelled a particularly long distance through the converter layer and therefore comprises a particularly high proportion of converted light, is attenuated more strongly, e.g. to reduce a yellowish color impression.

A concentration of converter particles in the converter layer may decrease in a direction towards the external side of the converter layer. In this way, it is possible to ensure that although the light emitted in the direction of the external side travels a longer distance through the converter layer, because of the lower concentration of converter particles in the outer region it is converted to approximately the same extent as light emitted in a perpendicular direction.

The converter layer may have a greater thickness in the center than at the external sides. This can be achieved, in a method step in which the semiconductor layer sequence is roughened by etching, e.g. by eroding more material in the center of the semiconductor layer sequence than in the outer region so that an indentation is obtained in the center. If the converter layer is then deposited e.g. in liquid or gel form, a converter layer is obtained which is thicker in the center. In this way, the distance travelled by the radiation through the converter material is increased for light emitted in a perpendicular direction to compensate at least partly for the greater distance through the converter material for light emitted in an oblique direction and thus to improve the color-over-angle homogeneity of the radiation.

Preferably, the n-contact layer comprises at least one n-through-contact routed through a gap in the p-type semiconductor region and the active layer into the n-type semiconductor region. In the region of the gap, the at least one n-through-contact is separated from the active layer and the p-type semiconductor region by an electrically insulating layer. The at least one p-contact feed-through is preferably at a distance from the at least one n-through-contact in a lateral direction. In other words, the n-through-contact or the multiple n-through-contacts do not lie above the p-contact feed-through or the multiple p-contact feed-throughs in a vertical direction. In a top view, therefore, there is advantageously no overlap between a p-contact feed-through and an n-through-contact at any point.

Advantageously, the p-contact layer is covered in some regions by an encapsulating layer. The encapsulating layer is preferably an inorganic dielectric layer, in particular an oxide or nitride layer such as e.g. a silicon oxide layer, an aluminum oxide layer or a silicon nitride layer.

In our method of producing the optoelectronic semiconductor chip, the reinforcing layer, and/or the p-contact feed-through is/are advantageously produced by electroplating. By electroplating, the reinforcing layer can in particular be produced with a comparatively high RMS roughness of at least 50 nm. This is in particular when a nickel layer or a copper layer is electroplated.

Furthermore, it is advantageous in the production method if the dielectric layer arranged on the metallic reinforcing layer at least in some regions is a silicon oxide layer produced by chemical vapor deposition from tetraethyl orthosilicate (TEOS). This method makes it possible for a layer having substantially the same roughness as the reinforcing layer to be deposited conformally on the reinforcing layer. The RMS roughness of the dielectric layer, like the RMS roughness of the metallic reinforcing layer, is preferably at least 50 nm, particularly preferably at least 200 nm.

Further advantageous examples of the method can be taken from the above description of the optoelectronic semiconductor component and vice versa.

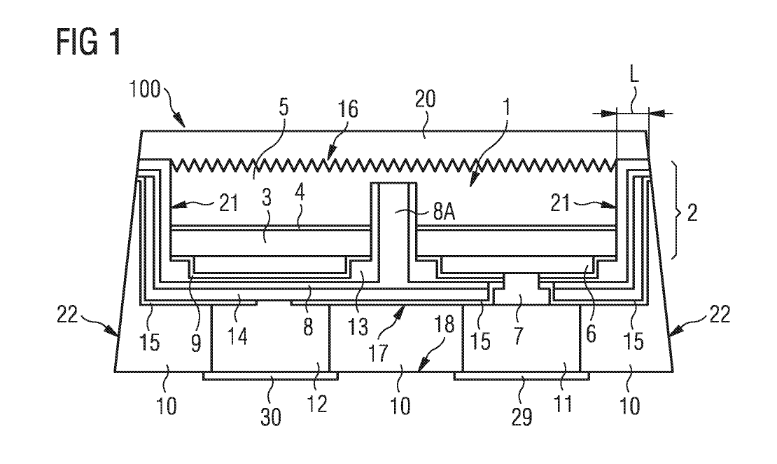

Our components and methods are explained in more detail below with the aid of examples in association with FIGS. 1 to 4.

Identical components or components having the same effect are each provided with the same reference numbers in the figures. The components illustrated and the size ratios to one another of the components should not be considered as being to scale.

The first example of an optoelectronic semiconductor component 100 illustrated in FIG. 1 is an LED. The LED comprises a semiconductor body 1 comprising a semiconductor layer sequence 2 having an active layer 4 capable of emitting radiation. The active layer 4 can comprise e.g. a p-n junction or a single or multiple quantum well structure for generating radiation. The active layer 4 is arranged between a p-type semiconductor region 3 and an n-type semiconductor region 5.

The semiconductor layer sequence 2 is preferably based on a III-V compound semiconductor material, in particular on an arsenide, nitride or phosphide compound semiconductor material. For example, the semiconductor layer sequence 2 can contain InₓAl_{y}Ga_{1-x-y}N, InₓAl_{y}Ga_{1-x-y}P or InₓAl_{y}Ga_{1-x-y}As, each with 0≤x≤1, 0≤y≤1 and x+y≤1. The III-V compound semiconductor material in this case does not necessarily have to have a mathematically exact composition according to one of the above formulae. Instead, it can comprise one or more dopants and additional constituents which do not substantially modify the physical properties of the material. For the sake of simplicity, however, the above formulae only contain the essential constituents of the crystal lattice although these can be partly replaced by small quantities of other substances.

The LED according to the examples is a so-called thin-film LED, from which a growth substrate used to grow the semiconductor layer sequence 2 has subsequently been detached from the semiconductor layer sequence 2. The original growth substrate, e.g. a sapphire, silicone or GaAs substrate, was detached from the side of the semiconductor body 1 on which the radiation exit surface 16 is now present. The semiconductor body 1 can be roughened or provided with a patterning on its radiation exit surface 16 to improve coupling of radiation out of the semiconductor body 1. The patterning or roughening of the semiconductor body 1 on the radiation exit surface 16 can take place in particular by an etching process.

On a surface opposite the radiation exit surface 16, the semiconductor body 1 is joined to a carrier 10. The carrier 10 is made of a plastic. In particular, the carrier 10 can be produced by compression molding, transfer molding or a casting method. The plastics material of the carrier 10 can comprise, for example, an epoxy resin or a silicone.

The carrier 10 has a first main surface 17 facing towards the semiconductor body 1 and a second main surface 18 facing away from the semiconductor body. The carrier 10 has a first via 11 and a second via 12, each routed from the first main surface 17 to the second main surface 18 of the carrier 10. The vias 11, 12 advantageously comprise a metal or a metal alloy and can be produced in particular by electroplating. The vias 11, 12 can contain, for example, Cu, Ni or a solder. The two vias 11, 12 are used for electrical contacting of the semiconductor body 1. For example, the first via 11 electrically joins the p-type semiconductor region 3 of the semiconductor layer sequence 2 and the second via 12 electrically joins the n-type semiconductor region 5.

On the rear side of the vias 11, 12, rear contacts 29, 30 can be deposited. The rear contacts can comprise, for example, a metal or a metal alloy, in particular a solder. The rear contacts 29, 30 can contain, for example, Au, Pd, Ag, Sn, Cu, Ni, Ti, Al, W and/or Pt. For example, the rear contacts 29, 30 are a CuSn, NiSn, CuNiSn, TiAu, TiPtAu, NiAu, TiAuSn, TiPtAuSn, NiAuSn or NiPdAu layer. The rear contacts 29, 30 can also be an SnAgCu layer (SAC solder layer), AuSn, CuAgNi layer or a pure Ag, Cu or Au layer.

In the example illustrated in FIG. 1, the rear contacts project over the vias 11, 12. Alternatively, however, it is also possible that the rear contacts 29, 30 are congruent with the vias 11, 12 or do not completely cover the vias 11, 12.

An electrically conductive join between the first via 11 and the p-type semiconductor region 3 is made in particular by a p-contact layer 6 that adjoins the p-type semiconductor region, for example, and a p-contact feed-through 7 arranged between the semiconductor body 1 and the carrier 10. The p-contact feed-through 7 joins the first via 11 to the p-contact layer 6. It is also possible that the p-contact feed-through 7 is part of the first via 11. For example, the p-contact feed-through 7 and the first via 11 can be produced simultaneously, e.g. by electroplating a metal or a metal alloy.

The second via 12 electrically joins the n-type semiconductor region 5 by an n-contact layer 8, 8A. This can take place e.g. by routing a part of the n-contact layer 8 through at least one gap through the semiconductor layer sequence 2 into the n-type semiconductor region 5, thus forming at least one through-contact 8A. The n-contact layer 8, 8A is electrically insulated from the p-type semiconductor region 3, the active layer 4, the p-contact layer 6 and the first via 11 by at least one electrically insulating layer 13. The at least one electrically insulating layer 13 can comprise, for example, a silicon oxide or aluminum oxide.

Contacting the optoelectronic component by the n-contact layer 8, 8A routed through the active zone 4 has the advantage that the contacting of both the n-type semiconductor region 5 and the p-type semiconductor region 3 takes place from the side of the semiconductor body 1 facing towards the carrier 10. The radiation exit surface 16 of the optoelectronic component is therefore advantageously free from electrical contact elements such as e.g. bond pads, contact metallizations or connecting wires. In this way, an absorption of radiation by contact elements on the radiation exit surface 16 is prevented.

On the second main surface 18 of the carrier 10 opposite the semiconductor body 1, the vias 11, 12 can advantageously be connected externally. In particular, the electrically conductive vias 11, 12 can be joined on the second main surface 18 of the carrier 10 e.g. to the traces of a printed circuit board. The optoelectronic semiconductor component is therefore advantageously surface-mountable.

Between the n-contact layer 8 and the carrier 10, a metallic reinforcing layer 14 is advantageously arranged. The metallic reinforcing layer 14 advantageously has a thickness of at least 5 μm, particularly preferably of at least 10 μm. The metallic reinforcing layer 14 contains a metal or a metal alloy, e.g. nickel or copper. Preferably, the reinforcing layer 14 is produced by electroplating. The reinforcing layer 14 preferably has an RMS roughness of at least 50 nm, particularly preferably of at least 200 nm. The comparatively high roughness of the reinforcing layer 14 has the advantage that the adhesion of a further electrically insulating layer 15 following it in the direction 10 of the carrier is improved.

The electrically insulating layer 15 between the carrier 10 and the reinforcing layer 14 improves adhesion of the plastics material of the carrier 10 to the optoelectronic component.

The side walls 21 of the semiconductor layer sequence 2 are covered at least in some regions, preferably completely, by a layer sequence comprising one or more electrically insulating layers 13, 15 and one or more metallic layers 8, 14. In particular, the side walls 21 of the semiconductor layer sequence 2 do not adjoin the carrier 10 directly. The plastics material of the carrier 10 is thus advantageously protected from the radiation generated in the active layer 4. The metallic reinforcing layer 14, which advantageously has a thickness of at least 5 μm, is preferably arranged at least in some regions between the side walls 21 of the semiconductor layer sequence 2 and the carrier body 10. In addition to the protection of the carrier body 10 from the radiation from the active layer 3, an improvement in mechanical stability is also achieved in this way. The long-term stability of the optoelectronic semiconductor component 100 is thus improved.

The electrically insulating layer 15 provides an electrical insulation of the reinforcing layer 14 from the p-contact feed-through 7 and the first via 11. The electrically insulating layer 15 comprises, for example, an inorganic dielectric material and is preferably less than 5 μm thick. The p-contact feed-through 7 and the reinforcing layer 14 are, at least in some regions, separated from one another only by the electrically insulating layer 15. In particular, the p-contact feed-through 7 is routed through the reinforcing layer 14 in a vertical direction, the reinforcing layer 14 being electrically joined to the n-contact layer 8 in the illustrated example and therefore having to be insulated from the p-contact feed-through 7 by the electrically insulating layer 15. The at least one p-contact feed-through 7 is preferably at a distance, in a lateral direction, from the at least one n-through-contact 8A, which leads to the n-type semiconductor region 5. In other words, the at least one p-contact feed-through 7 and the at least one n-through-contact 8A are not positioned one above the other in a vertical direction.

The metallic reinforcing layer 14 can adjoin the n-contact layer 8 at least in some regions, thus forming an electrically conductive join between the second via 12 and the n-contact layer 8. In particular, part of the second via 12 can extend through the electrically insulating layer 15 and adjoin the metallic reinforcing layer 14 to make electrical contact therewith. In other words, the second via 12 electrically joins the n-type semiconductor region 5 by way of the metallic reinforcing layer 14 and the n-contact layer 8, 8A.

In the example illustrated, a converter layer 20 is arranged on the radiation exit surface 16 of the semiconductor layer sequence 2. The converter layer 20 can in particular directly adjoin the semiconductor layer sequence 2, at least in some regions, and in particular is not separated from the semiconductor layer sequence 2 by a dielectric material. By the converter layer 20, at least part of the radiation emitted by the active layer 4 is converted to radiation having a greater wavelength. In this way, white light can be generated e.g. using a semiconductor chip emitting in the blue or UV range of the spectrum. To this end, the converter layer 20 advantageously comprises one or more conversion substances that can be embedded e.g. in a matrix material, for example, a silicone. The principle of luminescence conversion and suitable conversion substances are known and therefore not explained in more detail at this point.

The converter layer 20 extends beyond the semiconductor layer sequence 2 in a lateral direction by a length L, preferably at least 5 μm and no more than 50 μm. In this way, improved color homogeneity of the emitted radiation can advantageously be achieved and/or the color location of the emitted radiation can be adjusted in a targeted manner as a function of the angle of radiation.

The optoelectronic component 100 advantageously has oblique side walls 22. The side walls 22 are in particular inclined at an angle not equal to 90° in relation to a main plane of the semiconductor layer sequence 2. The oblique side walls 22 are advantageously inclined such that the optoelectronic component 100 tapers in a direction running from the carrier towards the radiation exit surface 16. The optoelectronic component 100 is therefore wider on a rear side that can be formed by the second main surface 18 of the carrier 10, than on a front side, on which the radiation exit surface 16 and optionally the converter layer 20 are arranged. The oblique configuration of the side walls 22 has the advantage that, when the optoelectronic semiconductor component 100 is gripped from the side, there is no risk of the gripping tool coming into contact with the converter layer 20. In this way, the risk of the gripping tool being contaminated by the converter layer 20, comprising e.g. a tacky silicone, is reduced.

The optoelectronic component 100 is preferably produced in a wafer composite with a plurality of further optoelectronic components of the same type. The oblique side walls 22 are preferably created when the wafer is separated into individual optoelectronic components 100. The separation can take place e.g. by sawing or laser cutting.

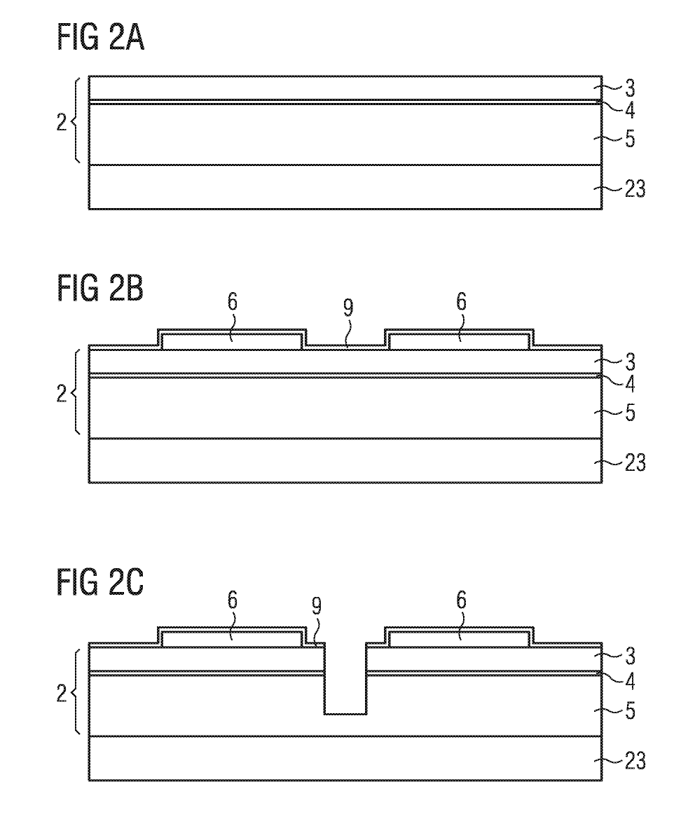

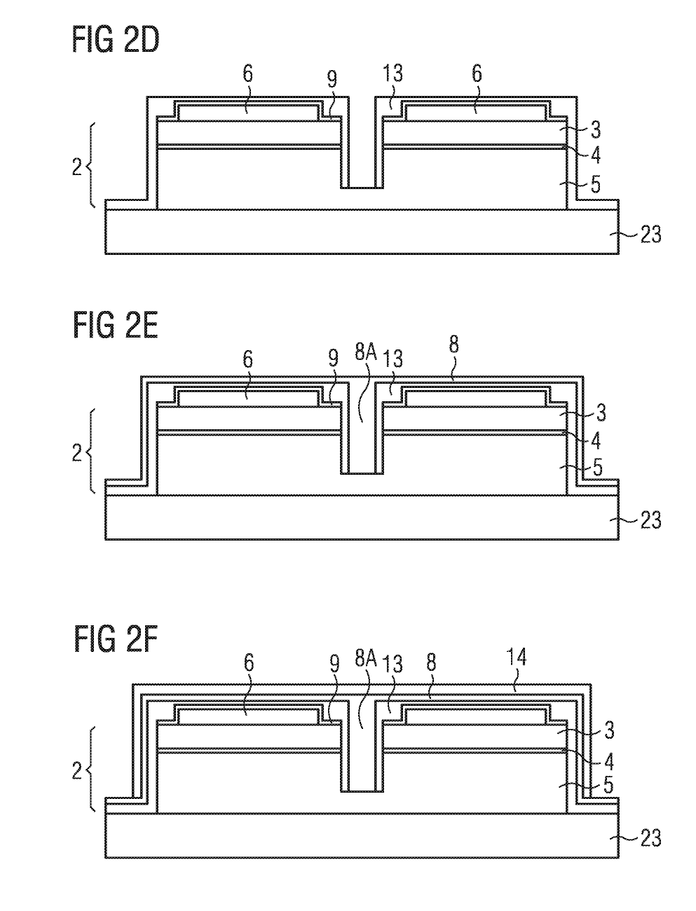

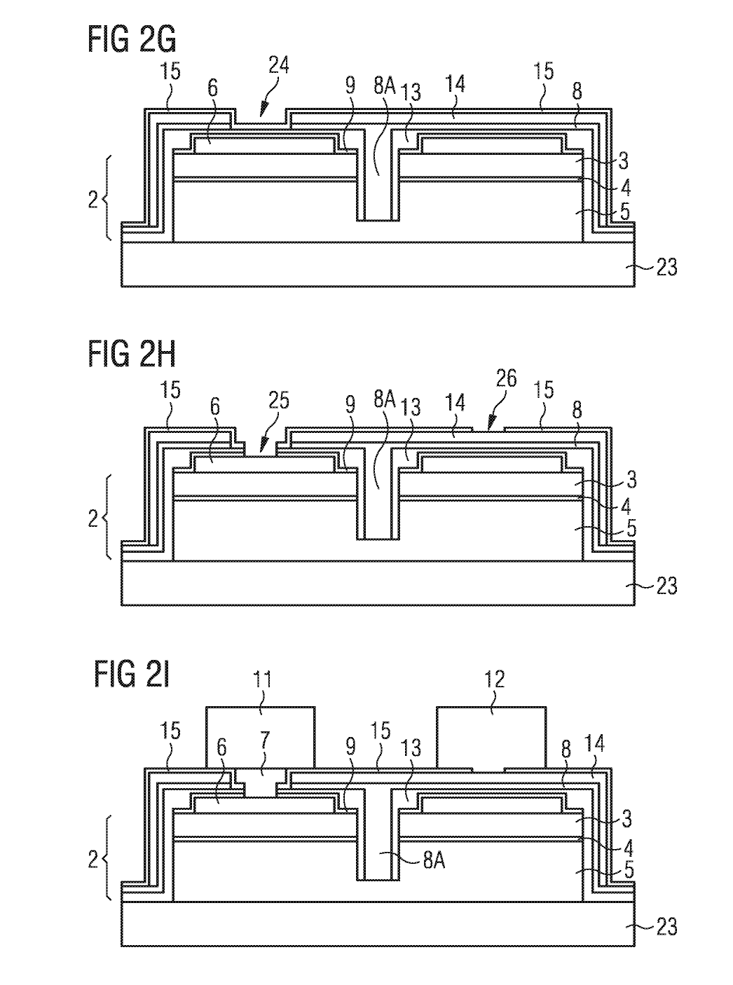

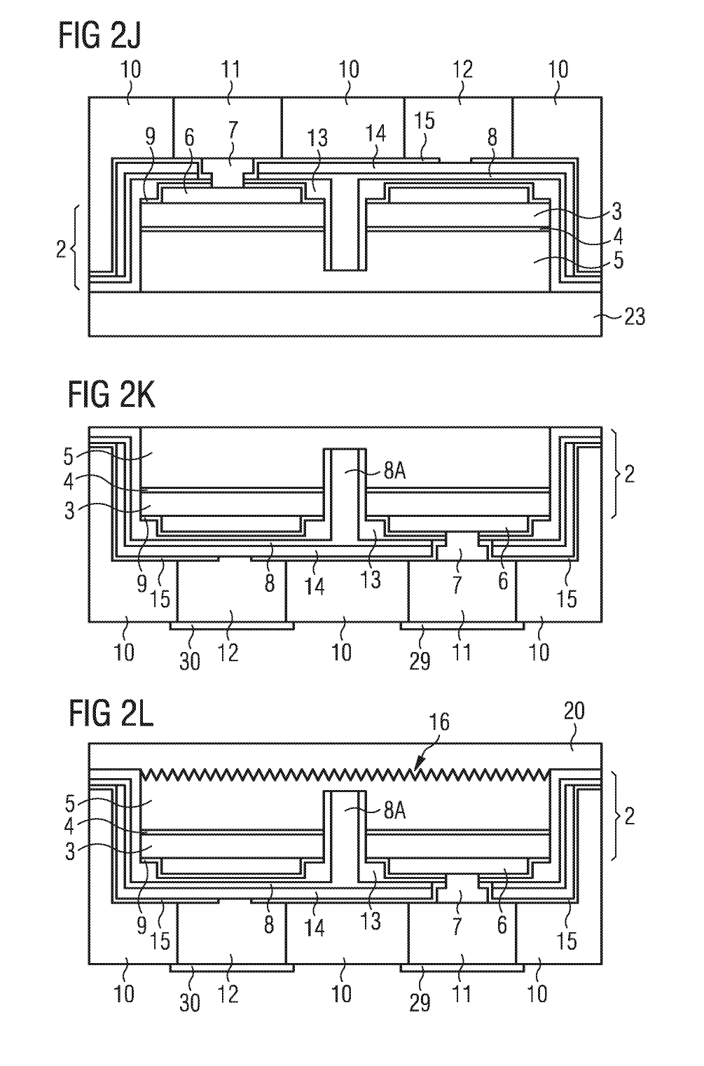

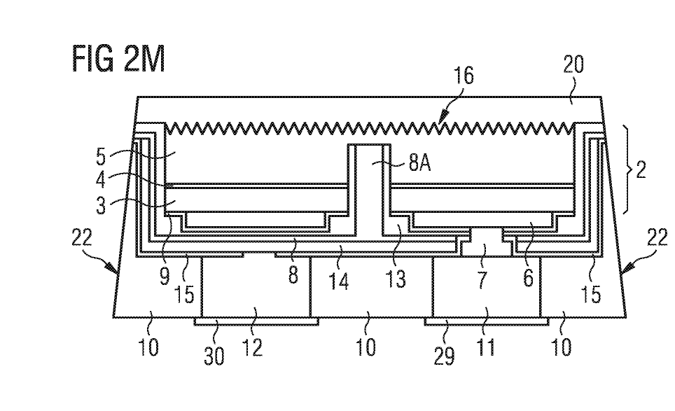

In the subsequent FIGS. 2A to 2M, an example of a method of producing the optoelectronic semiconductor component is described. The advantageous examples of individual parts of the optoelectronic semiconductor component described above apply in the same way to the method described below and vice versa.

In the intermediate step of the method illustrated in FIG. 2A, the semiconductor layer sequence 2 comprising the p-type semiconductor region 3, the active layer 4 and the n-type semiconductor region 5, has been grown on a growth substrate 23. The growth substrate 23 can comprise e.g. GaN, sapphire, GaAs, Si or SiC. The semiconductor layer sequence 2 is preferably produced epitaxially, in particular by metalorganic vapor phase epitaxy (MOVPE). The p-type semiconductor region 3, the active layer 4 and the n-type semiconductor region 5 can each be composed of multiple individual layers not illustrated individually for the sake of simplicity.

In the intermediate step illustrated in FIG. 2B, a p-contact layer 6 has been deposited on the semiconductor layer sequence 2 and patterned into sub-regions. The p-contact layer 6 preferably comprises a metal or a metal alloy and can be in particular a reflective layer. The p-contact layer 6 can comprise or consist of e.g. silver. It is also possible that the p-contact layer 6 is formed from multiple sub-layers. Furthermore, an encapsulating layer 9 has been deposited over the p-contact layer 6. The encapsulating layer 9 is preferably an inorganic dielectric layer, in particular an oxide or nitride layer such as e.g. a silicon oxide layer or a silicon nitride layer. Alternatively, the encapsulating layer can contain e.g. TiWN, TiN, TiW or Cr. The encapsulating layer 9 serves the purpose of, for example, electrically insulating the p-contact layer 6 from subsequent electrically conductive layers, in particular an n-contact layer, and/or protecting the p-contact layer 6.

In the intermediate step illustrated in FIG. 2C, a recess has been created in the semiconductor layer sequence 2, e.g. by an etching process, the recess extending into the n-type semiconductor region 5. The purpose of the recess is to feed an n-contact layer through into the n-type semiconductor region 5 in the further method.

In the intermediate step illustrated in FIG. 2D, a mesa structure has been created in the semiconductor layer sequence 2. To this end, the semiconductor layer sequence 2 has been eroded in the edge region, e.g. by an etching process to pattern it into a desired shape and size. The mesa structure preferably extends into the region of the growth substrate 23, i.e. the semiconductor layer sequence 2 is almost completely or completely eroded in the edge regions. In addition, in the intermediate step illustrated in FIG. 2D a further electrically insulating layer 13 has been deposited, which in particular covers and thus electrically insulates the side walls of the semiconductor layer sequence 2 in the etched trenches of the mesa structure and the recess. On the bottom of the recess, which was produced in the preceding intermediate step for the subsequent feed-through of the n-contact layer, the electrically insulating layer 13 has been removed to expose the n-type semiconductor region 5 there.

In the intermediate step illustrated in FIG. 2E, an n-contact layer 8 has been deposited. The n-contact layer 8 preferably comprises a metal or a metal alloy. In particular, the n-contact layer 8 can comprise a reflective metal such as e.g. aluminum or silver. In the region of the recess, the n-contact layer 8 extends through the p-type semiconductor region 3 and the active layer 4 into the n-type semiconductor region 5 and forms a through-contact 8A in this region. The n-contact layer 8 can cover the previously deposited electrically insulating layer 13 on the side walls of the semiconductor layer sequence 2.

In the intermediate step illustrated in FIG. 2F, a metallic reinforcing layer 14 has been deposited. The metallic reinforcing layer 14 is formed using a metal or a metal alloy and can be deposited in particular by electroplating. The reinforcing layer 14 can contain nickel, for example. For production of the metallic reinforcing layer 14 by electroplating, a seed layer can be previously deposited and optionally patterned (not illustrated). To deposit the metallic reinforcing layer in a patterned manner, it is also possible to employ photolithographic steps which are known per se, in particular using a resist mask.

Preferably, the reinforcing layer 14 is at least 5 μm, particularly preferably at least 10 μm, thick. The reinforcing layer 14 is in particular also arranged at least partly at the side of the semiconductor layer sequence 2. As a result of the reinforcing layer 14, mechanical stability is increased in subsequent process steps and in particular in the finished optoelectronic component.

In the intermediate step illustrated in FIG. 2G, at least one opening 24 has been created in the reinforcing layer 14 and the underlying n-contact layer 8, the opening 24 extending e.g. to the electrically insulating layer 13. Alternatively, it is possible to deposit the metallic reinforcing layer 14 in a patterned manner in the method step of FIG. 2F such that it already comprises one or more openings 24. Furthermore, a further electrically insulating layer 15 has been deposited over the reinforcing layer 14, which, like the encapsulating layer 9 or the electrically insulating layer 13 described above, can preferably comprise at least one inorganic dielectric material such as e.g. silicon oxide. The electrically insulating layer 15 preferably completely covers the surface of the reinforcing layer 14. In particular, the electrically conductive layers 8, 14 are covered by the electrically insulating layer 15 in the region of the opening 24.

The electrically insulating layer 15 is preferably a silicon dioxide layer, which is advantageously produced by CVD using tetraethyl orthosilicate. A conformal covering of the reinforcing layer 14 by the electrically insulating layer 15 can advantageously be achieved by using this method. The electrically insulating layer 15 thus advantageously has substantially the same roughness as the reinforcing layer 14. Preferably, the RMS roughness of the electrically insulating layer 15 is at least 50 nm, preferably at least 100 nm. The electrically insulating layer 15 covers the reinforcing layer 14 in particular conformally in the region of the at least one opening 24 to provide electrical insulation there.

In the intermediate step illustrated in FIG. 2H, at least one opening 25 has been created in the electrically insulating layers 13, 15 and the encapsulating layer 9 to expose the p-contact layer 6 and at least one further opening 26 has been created in the electrically insulating layer 15 to expose a region of the reinforcing layer 14.

In the intermediate step illustrated in FIG. 2I, the previously created opening has been filled over the p-contact layer 6 with a metallic layer, which forms a p-through-contact 7. The p-through-contact 7 is joined to a metallic contact layer, which in the finished component forms a first via 11 through a carrier. The first via 11 electrically joins the p-type semiconductor region 3 in this way by way of the p-through-contact 7 and the p-contact layer 6. Furthermore, in the intermediate step a second metallic contact layer, which in the finished component forms a second via 12 through a carrier, has been produced over the previously produced opening in the electrically insulating layer 15 arranged over the reinforcing layer 14. The second via 12 electrically joins the reinforcing layer 14 in this way and thus contacts the n-type semiconductor region 3 by way of the n-contact layer 8 with the through-contact 8A. It is possible that the first via 11, the second via 12 and/or the p-through-contact 7 are produced in one method step by electroplating. The p-through-contact 7 and the reinforcing layer 14 are arranged in one plane, at least in some regions, and are separated from one another only by a region of the electrically insulating layer 15, which is preferably less than 5 μm thick.

It is possible that, instead of a single p-contact feed-through 7, multiple p-contact feed-throughs 7 are created between the first via 11 and the p-contact layer 6 (not illustrated). In this variant, multiple openings are created in the reinforcing layer 14, the n-contact layer 8, the electrically insulating layer 13 and the encapsulating layer 9 in the preceding intermediate steps. The at least one p-contact feed-through 7 can have e.g. a circular cross section in a top view. If multiple p-contact feed-throughs 7 are formed, these can form e.g. an arrangement of multiple circles. The at least one p-contact feed-through 7 does not necessarily have to run perpendicularly, but can alternatively also run obliquely to the vertical direction and/or can have side walls with a curved shape. This improves the adhesion of the p-contact feed-through 7 to the electrically insulating layer 15, through which the p-contact feed-through 7 runs, and the overholding of the electrically insulating layer 15.

In the intermediate step illustrated in FIG. 2J, the side of the optoelectronic component facing away from the growth substrate 23 has been encapsulated with a plastics material to form a carrier 10 in this way. The carrier 10 can in particular comprise a polymer such as, for example, an SiO₂-filled epoxy, a silicone or a hybrid material. If the vias 11, 12 are covered when the plastics material of the carrier 10 is being deposited, these are exposed again, for example, by grinding, lapping, polishing, other mechanical processing steps, laser ablation, etching or a combination of multiple such method steps. Preferably, the vias 11, 12 are partially ground when the plastics material itself is being eroded.

In the intermediate step illustrated in FIG. 2K, the growth substrate 23 has been detached from the semiconductor layer sequence 2. Detaching the growth substrate 23 can take place, for example, by a laser lift-off method, etching or grinding. The optoelectronic semiconductor component is now illustrated upside down compared to the previous intermediate steps because the surface of the semiconductor layer sequence 2 now represents the front side and the carrier 10 the rear side of the optoelectronic semiconductor component. In addition, the rear sides of the vias 11, 12 have been provided with rear contacts 29, 30.

In the further intermediate step illustrated in FIG. 2L, the surface of the semiconductor layer sequence 2 acting as a radiation exit surface 16 has been roughened, in particular to improve the outcoupling of radiation. Furthermore, a converter layer 20 has been deposited, for example, by casting, compression molding, spray coating or lamination of a converter film. The converter layer 20 projects over the semiconductor layer sequence 2 preferably by at least 5 μm in a sideways direction. For example, the converter layer can protrude over the semiconductor layer sequence 2 by between at least 5 μm and no more than 50 μm in a sideways direction. The intermediate steps described hitherto are preferably carried out at the wafer stage, i.e. a plurality of optoelectronic semiconductor components of the same type are processed simultaneously next to one another.

In the further method step illustrated in FIG. 2M, oblique side walls 22 have been created, wherein this process step can take place in particular when a wafer is singulated into individual optoelectronic components. If a converter layer 20 is present, the singulation preferably takes place by laser cutting using a picosecond laser or by a water-jet-guided process to minimize the thermal load on the converter layer 20. In this way, the optoelectronic semiconductor component 100 illustrated in FIG. 1 can be produced by way of example.

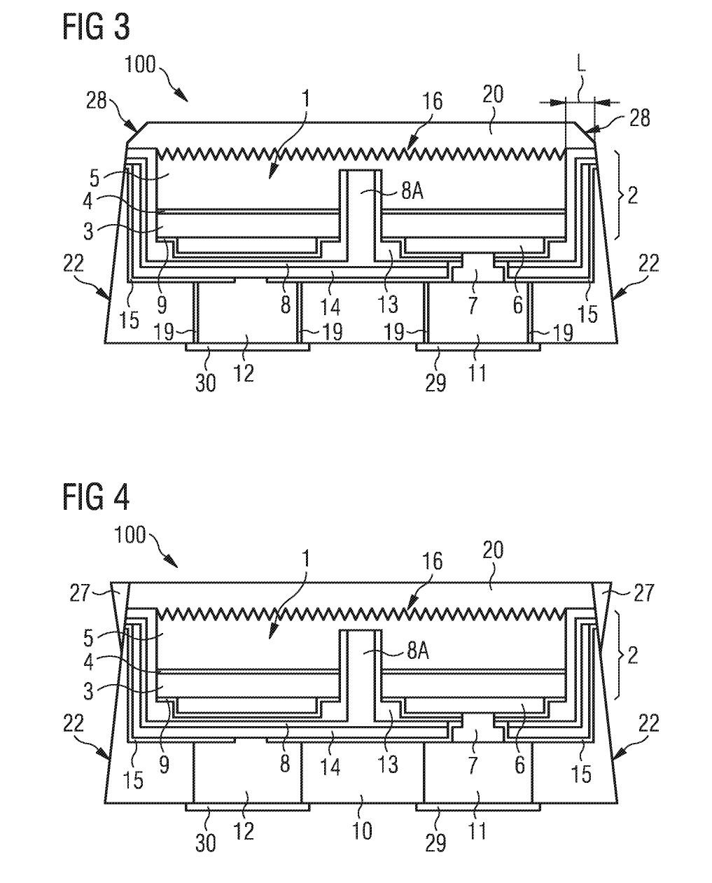

The second example of the optoelectronic semiconductor component 100 illustrated in FIG. 3 differs from the example illustrated in FIG. 1 by the fact that the converter layer has a chamfer 28, i.e. an edge that slopes on the external side of the surface. The chamfer can form a 45° angle with the surface of the converter layer 20, for example. Alternatively, the converter layer 20 can have a rounded edge. In this way, the homogeneity (color over angle) of the emitted radiation can advantageously be improved. In terms of further examples and the associated advantages, the second example corresponds to the first example.

Between the vias 11, 12 and the carrier 10, an electrically insulating layer 19 is advantageously arranged in each case. In this way, the adhesion of the plastics material of the carrier 10 to the metallic vias 11, 12 is improved. The electrically insulating layer 19 comprises a dielectric material different from the material of the carrier. In particular, the electrically insulating layer 19 can comprise an inorganic dielectric material.

In the third example of the optoelectronic semiconductor component 100 illustrated in FIG. 4, a light-absorbing or reflective layer 27 has been deposited on the side surfaces of the converter layer 20. In this way, a lateral emission by the converter layer 20 is reduced and the color homogeneity of the emitted radiation is improved in this way. The light-absorbing layer 27 has a varying thickness, which increases towards a surface of the converter layer 20. In this way, the light emitted at the upper edge of the converter layer 20, which has travelled a particularly long distance through the converter layer 20 and therefore has a particularly high proportion of converted light, is attenuated more strongly, e.g. to reduce a yellowish color impression.

Furthermore, the example illustrated in FIG. 4 differs from the example of FIG. 1 by the fact that the n-contact layer 8 does not adjoin the side walls 22 of the optoelectronic semiconductor chip at any point. This is advantageous in particular if the n-contact layer 8 comprises a metal such as, for example, silver, which is sensitive to environmental influences such as in particular humidity. To ensure that the n-contact layer 8 does not adjoin the side walls of the chip in the finished optoelectronic semiconductor component 100, the n-contact layer 8 is applied in a patterned manner, for example, in the method step of FIG. 2E such that it does not reach the side walls of the growth substrate 23 in a lateral direction and thus, in the subsequent method steps, is covered in particular by the dielectric layer 15 at the sides.

In terms of further examples and the associated advantages, the third example corresponds to the first example.

This description with the aid of the examples does not limit our components and methods thereto. Rather, our components and methods comprise any new feature and any combination of features, which in particular includes any combination of features in the appended claims, even if the feature or combination is not itself explicitly stated in the claims or examples.

This application claims priority of DE 10 2015 114 587.1, the subject matter of which is incorporated herein by reference.

1.-19. (canceled)

20. An optoelectronic semiconductor component comprising:
a semiconductor body comprising a semiconductor layer sequence having a p-type semiconductor region, an n-type semiconductor region and an active layer arranged between the p-type semiconductor region and the n-type semiconductor region,
a carrier comprising a plastic and a first via and a second via,
a p-contact layer and an n-contact layer arranged between the carrier and the semiconductor body at least in some regions, wherein the p-contact layer electrically joins the first via and the p-type semiconductor region, and the n-contact layer electrically joins the second via and the n-type semiconductor region,
a metallic reinforcing layer arranged at least in some regions between the n-contact layer and the carrier, wherein the metallic reinforcing layer is at least 5 μm thick, and
at least one p-contact feed-through arranged between the first via and the p-contact layer, wherein the p-contact feed-through is at least 5 μm thick and surrounded in a lateral direction by the reinforcing layer at least in some regions.

21. The optoelectronic semiconductor component according to claim 20, wherein the metallic reinforcing layer comprises or consists of nickel or copper.

22. The optoelectronic semiconductor component according to claim 20, wherein the metallic reinforcing layer has an RMS roughness of at least 50 nm at an interface facing towards the carrier.

23. The optoelectronic semiconductor component according to claim 20, wherein a dielectric layer is arranged between the carrier and the metallic reinforcing layer.

24. The optoelectronic semiconductor component according to claim 23, wherein the dielectric layer is arranged at least partly between the metallic reinforcing layer and the p-contact feed-through.

25. The optoelectronic semiconductor component according to claim 20, wherein the semiconductor layer sequence is surrounded by the carrier in a lateral direction, at least in some regions.

26. The optoelectronic semiconductor component according to claim 25, wherein the reinforcing layer is arranged between the semiconductor layer sequence and the carrier in some regions when viewed in a lateral direction.

27. The optoelectronic semiconductor component according to claim 20, wherein the optoelectronic semiconductor component comprises oblique side walls formed at least in some regions by external sides of the carrier, and the side walls run obliquely such that a cross section of the optoelectronic semiconductor component tapers from the carrier towards a radiation exit surface.

28. The optoelectronic semiconductor component according to claim 20, wherein a converter layer is arranged on a radiation exit surface of the optoelectronic semiconductor component.

29. The optoelectronic semiconductor component according to claim 28, wherein the converter layer projects over the semiconductor layer sequence by a length L of at least 5 μm in a lateral direction.

30. The optoelectronic semiconductor component according to claim 28, wherein the converter layer comprises a chamfer.

31. The optoelectronic semiconductor component according to claim 28, wherein side surfaces of the converter layer are covered with a light-absorbing or reflective layer.

32. The optoelectronic semiconductor component according to claim 31, wherein the light-absorbing layer has a thickness that increases towards the surface of the converter layer.

33. The optoelectronic semiconductor component according to claim 20, wherein the carrier comprises an epoxy resin or a silicone.

34. The optoelectronic semiconductor component according to claim 20, wherein the n-contact layer comprises at least one n-through-contact routed through a gap in the p-type-semiconductor region and the active layer into the n-type semiconductor region.

35. The optoelectronic semiconductor component according to claim 20, wherein the at least one p-contact feed-through is at a distance from the at least one n-through-contact in a lateral direction.

36. The optoelectronic semiconductor component according to claim 20, wherein the p-contact layer is covered in some regions by an inorganic dielectric encapsulating layer.

37. A method of producing an optoelectronic semiconductor component according to claim 20, comprising producing the reinforcing layer and the p-contact feed-through by electroplating.

38. The method according to claim 37, further comprising arranging a dielectric layer between the carrier and the metallic reinforcing layer, wherein the dielectric layer is a silicon oxide layer and is produced by CVD from tetraethyl orthosilicate.
